(19) United States
(12) Patent Application Publication
(10) Pub. No.: US 2009/0212409 A1
(43) Pub. Date: Aug. 27, 2009

(54) Stackable Semiconductor Package and Stack Method Thereof

(75) Inventor: Kyung Suk Kang, Yongin-si (KR)

Correspondence Address: Hyun Jong Park;TUCHMAN & PARK LLC, 41 White Birch Road, Redding, CT, 06896-2209, US

(73) Assignee: Memory & Testing Inc., Yongin-si (KR)

(21) Appl. No.: 12/110,201

(22) Filed: Apr. 25, 2008

(30) Foreign Application Priority Data
Feb. 25, 2008 (KR) 10-2008-0016929

(51) Int. Cl. H01L 23/02; H01L 21/00

(52) U.S. Cl. 257/686; 438/109; 257/E23.085

(57) ABSTRACT

A stackable semiconductor package is disclosed. In the stackable semiconductor package, land grid array (LGA) or ball grid array (BGA) semiconductor packages are stacked in the vertical direction. The stackable semiconductor package comprises: a first semiconductor package including a first substrate, at least one first semiconductor die mounted on the first substrate to be electrically connected to the first substrate, and a first encapsulant molded on the first substrate to surround the first semiconductor die; a second semiconductor package including a second substrate, at least one second semiconductor die mounted on the second substrate to be electrically connected to the second substrate, and a second encapsulant molded on the second substrate to surround the second semiconductor die; and one or more interposers positioned between the first and second semiconductor packages to electrically connect the first substrate to the second substrate so that the first and second semiconductor packages are stacked in the vertical direction. Further disclosed is stack method of semiconductor package.

### FIELD OF THE INVENTION

The present invention relates to a stackable semiconductor package and stack method thereof.

### BACKGROUND OF THE INVENTION

In general, stacks in the field of semiconductor packaging can be largely classified into two types: chip stack and package stack. The chip stack refers to a stack of a plurality of semiconductor chips in the vertical direction, and the package stack refers to a stack of a plurality of packages in the vertical direction.

Chip stack and package stack have attracted more and more attention in recent years due to the possibility that highly integrated high-performance semiconductor packages relative to the area of packages can be fabricated by increasing the volume density of the packages in the thickness direction. For example, a variety of devices, including flash memories, static random access memories (SRAMs), dynamic random access memories (DRAMs), baseband devices, mixed signal devices, analog devices and logic devices, are stacked in the vertical direction to achieve a greatly improved system integration and contribute to the reduction in the size, weight and price of mobile electronic communication devices.

On the other hand, lead frames, rigid circuit boards, flexible circuit boards and the like are used as representative substrates of semiconductor packages. A typical lead frame includes a plurality of leads protruding outwardly from and curved downwardly along sides of an encapsulant to enable stacking of semiconductor packages in the vertical direction. As an example, in a thin small outline package (TSOP), leads protruding outwardly from and curved downwardly along sides of an encapsulant of a first package are electrically connected to leads and solders of a second package positioned on or under the first package to enable stacking of the plural semiconductor packages in the vertical direction.

A typical rigid or flexible circuit board is provided with a plurality of lands or solder balls in a land grid array or ball grid array on its bottom surface, which makes it difficult to stack a plurality of semiconductor packages in the vertical direction. Specifically, a first circuit board of a first semiconductor package is positioned on an encapsulant of a second semiconductor package or an encapsulant of a third semiconductor package is positioned under a second circuit board of the second semiconductor package, making it difficult to electrically connect lands or solder balls of the semiconductor packages in the vertical direction. As a result, the semiconductor packages are difficult to stack.

### SUMMARY OF THE INVENTION

The present invention has been made in view of the problems of the prior art, and it is one aspect of the present invention to provide a stackable semiconductor package in which land grid array (LGA) or ball grid array (BGA) semiconductor packages can be stacked in the vertical direction.

It is another aspect of the present invention to provide a stack method of stackable semiconductor package.

In accordance with one embodiment of the present invention for accomplishing the above aspects, there is provided a stackable semiconductor package comprising a substrate, at least one semiconductor die mounted on the substrate to be electrically connected to the substrate, and an encapsulant molded on the substrate to surround the semiconductor die wherein the substrate is formed with at least one extension extending outside the outer circumference of the encapsulant and the extension is provided with upper and lower conductive pads electrically connected to one another and exposed to the outside for package stacking on its upper and lower surfaces.

In accordance with another embodiment of the present invention, there is provided a stackable semiconductor package comprising: a first semiconductor package including a first substrate, at least one first semiconductor die mounted on the first substrate to be electrically connected to the first substrate, and a first encapsulant molded on the first substrate to surround the first semiconductor die; a second semiconductor package including a second substrate, at least one second semiconductor die mounted on the second substrate to be electrically connected to the second substrate, and a second encapsulant molded on the second substrate to surround the second semiconductor die; and one or more interposers positioned between the first and second semiconductor packages to electrically connect the first substrate to the second substrate so that the first and second semiconductor packages are stacked in the vertical direction.

Preferably, the first substrate is formed with at least one first extension extending outside the outer circumference of the first encapsulant, and the first extension is provided with first upper and lower conductive pads electrically connected to the interposers and one another on its upper and lower surfaces.

Preferably, the second substrate is formed with at least one second extension extending outside the outer circumference of the second encapsulant, and the second extension is provided with second upper and lower conductive pads electrically connected to the interposers and one another on its upper and lower surfaces.

Each of the interposers includes an insulating layer, lower conductive pads formed on the lower surface of the insulating layer to be electrically connected to the first substrate of the first semiconductor package, and upper conductive pads formed on the upper surface of the insulating layer opposite to the lower conductive pads to be electrically connected to the second substrate of the second semiconductor package, the upper and lower conductive pads being electrically connected to one another.

Preferably, the interposers are electrically connected to the first substrate and the second substrate by lower solder balls and upper solder balls, respectively.

Preferably, one to four interposers are formed between the first and second substrates.

Preferably, the shape of the interposers between the first and second substrates is selected from ‘—’, [symbol] and ‘□’ shapes.

In accordance with still another embodiment of the present invention, there is provided a stack method of stackable semiconductor package, the method comprising the steps of: mounting at least one first semiconductor die on a first substrate to electrically connect the first substrate to the first semiconductor die, and encapsulating the first semiconductor die with a first encapsulant to prepare a first semiconductor package; mounting at least one second semiconductor die on a second substrate to electrically connect the second substrate to the second semiconductor die, and encapsulating the second semiconductor die with a second encapsulant to prepare a second semiconductor package; preparing one or more interposers, each of which includes an insulating layer, lower conductive pads and lower solder balls sequentially formed on the lower surface of the insulating layer, and upper conductive pads and upper solder balls sequentially formed on the upper surface of the insulating layer; positioning and aligning the interposers between the first and second substrates such that the lower solder balls come into contact with the first substrate and the upper solder balls come into contact with the second substrate; placing the first semiconductor package, the second semiconductor package and the interposers in a furnace at a temperature of 180 to 300° C. to melt the upper and lower solder balls so that the lower solder balls are electrically connected to the first substrate and the upper solder balls are electrically connected to the second substrate (reflow); and cooling the first semiconductor package, the second semiconductor package and the interposers to room temperature to cure the upper and lower solder balls.

Preferably, in the step of preparing the first semiconductor package, the first substrate is formed with at least one first extension extending outside the outer circumference of the first encapsulant, and the first extension is provided with first upper and lower conductive pads electrically connected to the interposers and one another on its upper and lower surfaces.

Preferably, in the step of preparing the second semiconductor package, the second substrate is formed with at least one second extension extending outside the outer circumference of the second encapsulant, and the second extension is provided with second upper and lower conductive pads electrically connected to the interposers and one another on its upper and lower surfaces.

Preferably, in the step of preparing the interposers, each of the interposers includes an insulating layer, lower conductive pads formed on the lower surface of the insulating layer to be electrically connected to the first substrate of the first semiconductor package, and upper conductive pads formed on the upper surface of the insulating layer opposite to the lower conductive pads to be electrically connected to the second substrate of the second semiconductor package, the upper and lower conductive pads being electrically connected to one another.

Preferably, in the step of preparing the interposers, lower solder balls are attached to the lower conductive pads and upper solder balls are attached to the upper conductive pads.

Preferably, in the step of preparing the interposers, one to four interposers are formed between the first and second substrates.

Preferably, in the step of preparing the interposers, the shape of the interposers between the first and second substrates is selected from ‘—’, [symbol] [symbol] and ‘□’ shapes.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a, 1b and 1c are a perspective view, a plan view and a bottom view showing a first semiconductor package of a stackable semiconductor package according to an embodiment of the present invention, respectively;

FIG. 2 is a longitudinal cross-sectional view showing a first semiconductor package of a stackable semiconductor package according to an embodiment of the present invention;

FIGS. 3a and 3b are a longitudinal cross-sectional view and an exploded perspective view showing a stackable semiconductor package according to an embodiment of the present invention, respectively;

FIGS. 4a and 4b are a longitudinal cross-sectional view and an exploded perspective view showing a stackable semiconductor package according to another embodiment of the present invention, respectively;

FIG. 5 is an exploded perspective view showing a stackable semiconductor package according to another embodiment of the present invention;

FIG. 6 is an exploded perspective view showing a stackable semiconductor package according to another embodiment of the present invention;

FIG. 7 is an exploded perspective view showing a stackable semiconductor package according to another embodiment of the present invention;

FIG. 8 is a flow chart illustrating a stack method of a stackable semiconductor package according to the present invention; and

FIGS. 9a through 9d are cross-sectional views sequentially illustrating a stack method of a stackable semiconductor package according to the present invention.

### DETAILED DESCRIPTION OF THE INVENTION

Preferred embodiments of the present invention will now be described in detail with reference to the accompanying drawings in such a manner that they can be readily carried out by those having ordinary skill in the technical art to which the present invention pertains.

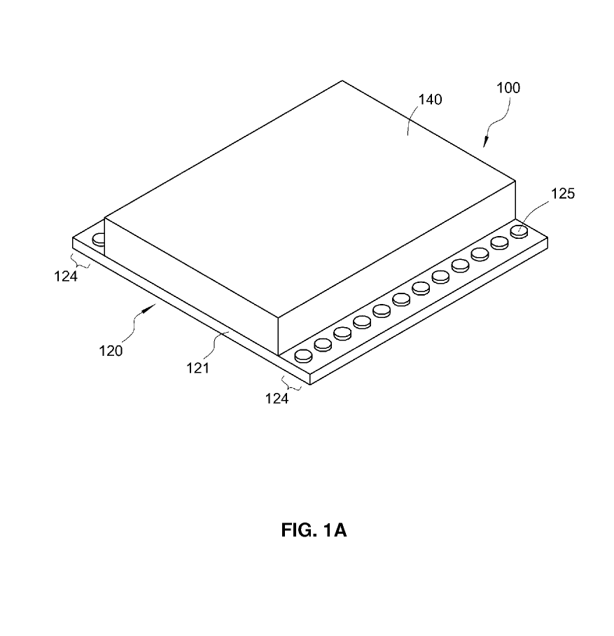

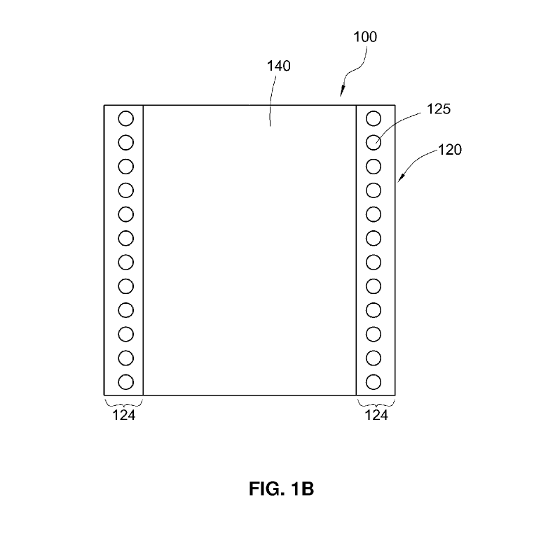

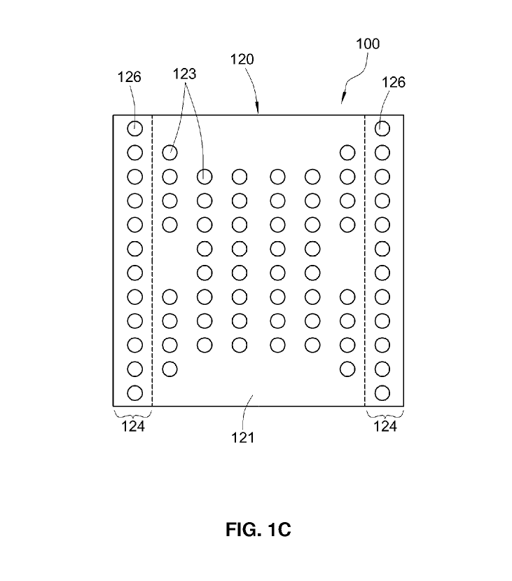

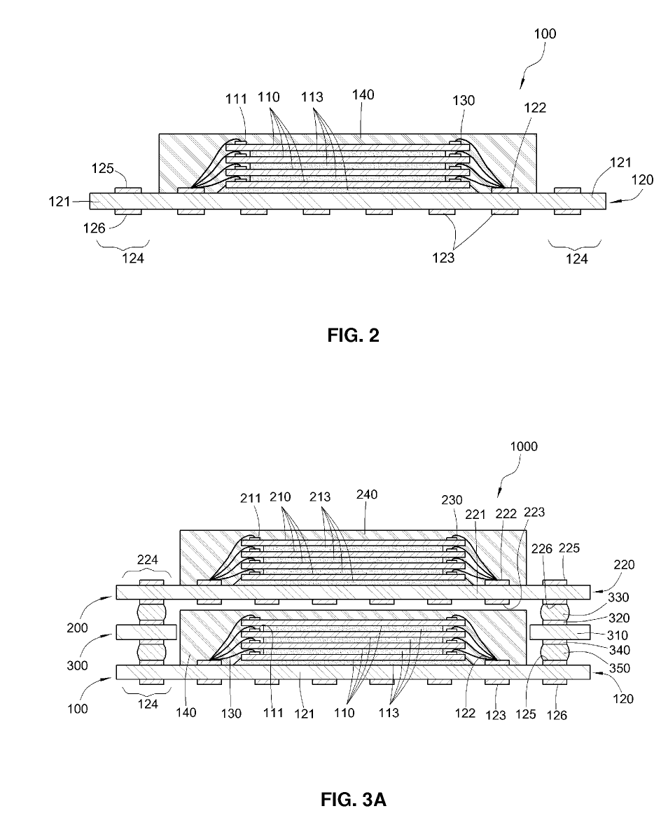

FIGS. 1a, 1b and 1c are a perspective view, a plan view and a bottom view showing a first semiconductor package of a stackable semiconductor package according to an embodiment of the present invention, respectively; and FIG. 2 is a longitudinal cross-sectional view showing a first semiconductor package of a stackable semiconductor package according to an embodiment of the present invention.

As shown in the figures, the first semiconductor package 100 of the stackable semiconductor package according to the present invention includes one or more first semiconductor dies 110, a first substrate 120, first conductive wires 130 and a first encapsulant 140.

For example, each of the first semiconductor dies 110 is a silicon or germanium semiconductor on which electronic circuits are integrated, and is provided with a plurality of first bond pads 111 inputting and outputting electrical signals on its one surface. The plural first semiconductor dies 110 can be stacked in the vertical direction. It should be noted that adhesives or spacers 113 are interposed between the respective first semiconductor dies 110 to fix the first semiconductor dies 110 and prevent the conductive wires 130 from damage. Although FIG. 2 shows a stack of four first semiconductor dies 110, the number of the first semiconductor dies 110 may be greater or smaller than four. Of course, the first semiconductor dies 110 may not be stacked. A variety of passive elements, such as capacitors, inductors and resistors, may be positioned around the semiconductor dies on which integrated circuits are formed.

The first substrate 120 includes a first insulating layer 121, a plurality of first upper conductive pads 122 formed on the upper surface of the first insulating layer 121 and a plurality of first lower conductive pads 123 formed on the lower surface of the first insulating layer 121. The first lower conductive pads 123 may be arrayed in a lattice pattern. Namely, the first lower conductive pads 123 in a land grid array (LGA) configuration may be directly mounted on an external device. Further, the first upper conductive pads 122 and the first lower conductive pads 123 can be electrically connected to one another through respective conductive vias (not shown). Portions of the first substrate 120 extending outside the periphery of the first encapsulant 140 are defined as first extensions 124. Each of the first extensions 124 is provided with first upper conductive pads 125 on its upper surface and first lower conductive pads 126 on its lower surface. It is to be understood that the first upper conductive pads 125 and the first lower conductive pads 126 can be electrically connected to one another through respective conductive vias (not shown). Furthermore, the first lower conductive pads 126 of the first extensions 124 can be electrically connected to the first lower conductive pads 123 formed in the lower region of the first insulating layer 121 opposite to the first encapsulant 140 through line patterns or circuit patterns (not shown). The reason for this electrical connection between the first lower conductive pads 126 and the first lower conductive pads 123 is to transmit all electrical signals to the first lower conductive pads 126 of the first extensions 14 through the first lower conductive pads 123 opposite to the first encapsulant 140 upon stacking of packages. The first substrate 120 may be selected from flexible circuit boards, rigid circuit boards and equivalents thereof. There is no particular restriction on the kind of the first substrate 120. The first semiconductor dies 110 can be adhered to the upper surface of the first substrate 120 by means of a suitable material, such as an adhesive.

The first conductive wires 130 serve to electrically connect the first bond pads 111 of the first semiconductor dies 110 to the first upper conductive pads 122 of the first substrate 120. Accordingly, electrical signals from the first semiconductor dies 110 can be transmitted to an external device through the first bond pads 111, the first conductive wires 130, the first upper conductive pads 122 and the first lower conductive pads 123. Upon stacking of packages, of course, the electrical signals from the first semiconductor dies 110 are transmitted to the first lower conductive pads 126 formed under the first extensions 124. Meanwhile, electrical signals from the external device can be delivered to the first semiconductor dies 110 in the reverse order. Instead of the conductive wires, conductive bumps can be used as members for electrical connection between the first semiconductor dies 110 and the first substrate 120. There is no restriction on the method for electrical connection between the first semiconductor dies 110 and the first substrate 120. For example, the first semiconductor dies 110 can be electrically connected to the first substrate 120 by a suitable method known as flip-chip connection or controlled-collapse chip connection (C4). In the case where flip-chip connection or controlled-collapse chip connection (C4) is used, underfill may be interposed between the first semiconductor dies 110 and the first substrate 120.

The first encapsulant 140 encapsulates the first semiconductor dies 110 formed on the first substrate 120, the first conductive wires 130 and the first upper conductive pads 122 electrically connected to the first conductive wires 130 to protect them from the external environment. That is, the first encapsulant 140 is formed by molding on the upper surface of the first substrate 120. Examples of suitable materials for the first encapsulant 140 include, but are not limited to, common epoxy molding compounds, plastic resins and equivalents thereof. The first encapsulant 140 is formed so as not to cover the first extensions 124 of the first substrate 120. That is, the first extensions 124 of a prescribed length protrude and extend horizontally outside the periphery of the first encapsulant 140. The first upper conductive pads 125 and the first lower conductive pads 126 formed on and under the first extensions 124 are exposed from the first encapsulant 140. The first extensions 124 of the stackable semiconductor package serve as basic structures on which a plurality of packages can be stacked.

As illustrated, the first semiconductor package 100 of the stackable semiconductor package according to the present invention can be directly mounted on an external device by the plural first lower conductive pads 123 in an LGA configuration. Further, the first extensions 124 formed horizontally outside the periphery of the first encapsulant 140 serve as basic structures for package stacking.

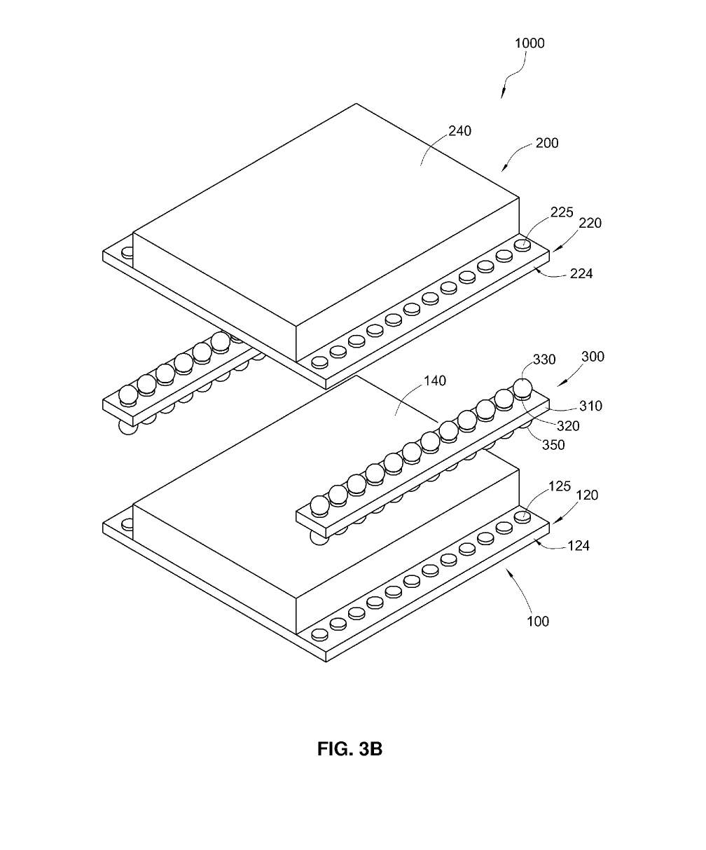

FIGS. 3a and 3b are a longitudinal cross-sectional view and an exploded perspective view showing a stackable semiconductor package according to an embodiment of the present invention, respectively.

As shown in FIGS. 3a and 3b, the stackable semiconductor package 1000 of the present invention comprises a first semiconductor package 100, a second semiconductor package 200, and interposers 300 electrically connecting the first semiconductor package to the second semiconductor package.

Herein, the second semiconductor package 200 is defined as being positioned on the first semiconductor package 100. Namely, it is assumed that the second semiconductor package 200 is stacked in the vertical direction on the first semiconductor package 100.

The structure of the second semiconductor package 200 may be substantially the same as that of the first semiconductor package 100, and detailed description thereof is omitted. For a better understanding of the present invention, the second semiconductor package 200 is defined to include second semiconductor dies 210, each of which has second bond pads 211, a second substrate 220 having an second insulating layer 221, second upper conductive pads 222, second lower conductive pads 223 and second extensions 224, second conductive wires 230, and an second encapsulant 240. Each of the second extensions 224 is provided with second upper conductive pads 225 on its upper surface and second lower conductive pads 226 on its lower surface. Given that the second semiconductor package 200 has the same structure as the first semiconductor package 100 for ease of illustration, an explanation of the second semiconductor package 200 will be provided below. It should, however, be noted that the structure of the second semiconductor package 200 may be different from that of the first semiconductor package 100.

Each of the interposers 300 includes an insulating layer 310, upper conductive pads 320, upper solder balls 330, lower conductive pads 340 and lower solder balls 350. The interposers 300 are essential elements of the stackable semiconductor package according to the present invention for stacking and electrical connection of packages, and therefore, a more detailed explanation thereof will be given below.

The insulating layer 310 is formed in a plate-like shape. A material for the insulating layer 310 is substantially identical to that for a first insulating layer 121 of a first substrate 120 or the second insulating layer 221 of the second substrate 220. Examples of suitable materials for the insulating layer 310 include, but are not limited to, polyimide and its equivalents.

The upper conductive pads 320 are formed on the upper surface of the insulating layer 310. The upper conductive pads 320 may be made of the same material as first and second conductive pads 122, 125, 222 and 225, which are formed on the first substrate 120, its first extension 124, the second substrate 220 and its second extension 224, respectively. Examples of suitable materials for the upper conductive pads 320 include, but are not limited to, copper foils and equivalents thereof.

The upper solder balls 330 are electrically and mechanically connected to the upper conductive pads 320. Examples of suitable materials for the upper solder balls 330 include, but are not limited to, lead (Pb)/tin (Sn), lead-free tin and equivalents thereof. A solder paste may be applied to the upper conductive pads 320, instead of the solder balls.

The lower conductive pads 340 are formed on the lower surface of the insulating layer 310. The lower conductive pads 340 may be made of the same material as first and second conductive pads 123, 126, 223 and 226, which are formed under the first substrate 120, the first extension 124 of the first substrate 120, the second substrate 220 and the second extension 224 of the second substrate 220, respectively. Examples of suitable materials for the lower conductive pads 340 include, but are not limited to, copper foils and equivalents thereof.

The lower solder balls 350 are electrically and mechanically connected to the lower conductive pads 340. Examples of suitable materials for the lower solder balls 350 include, but are not limited to, lead/tin, lead-free tin and equivalents thereof. A solder paste may be applied to the lower conductive pads 340, instead of the solder balls.

The upper conductive pads 320 are electrically connected to the lower conductive pads 340, thereby maintaining an electrical connection between the upper solder balls 330 and the lower solder balls 350.

The interposers 300 are spaced at a certain distance and are in the shape of a rectangular plate (‘—’). The interposers 300 can be disposed at both sides of the first encapsulant 140 of the first semiconductor package 100. That is, the interposers 300 can be positioned on the first extensions 124 of the first substrate 120 of the first semiconductor package 100. In other words, the interposers 300 can be interposed between the first extensions 124 of the first substrate 120 and the second extensions 224 of the second substrate 220.

The upper solder balls 330 of the interposers 300 can be electrically connected to the second lower conductive pads 226 formed under the second substrate 220 of the second semiconductor package 200, and the lower solder balls 350 of the interposers 300 can be electrically connected to the first upper conductive pads 125 formed on the first substrate 120 of the second semiconductor package 100.

With this configuration, the interposers 300 serve not only to stack the first semiconductor package 100 and the second semiconductor package 200 in the vertical direction, but also to electrically connect the first semiconductor package 100 to the second semiconductor package 200. Although FIGS. 3a and 3b show a stack of the two semiconductor packages in the vertical direction, there is no restriction on the number of semiconductor packages stacked. Three or more semiconductor packages may be stacked. As the number of semiconductor packages stacked increases, the number of interposers necessary for stacking of the semiconductor packages increases.

A clearance of a prescribed width may be provided between the first semiconductor package 100 and the second semiconductor package 200, i.e. between the first encapsulant 140 of the first semiconductor package 100 and the second substrate 220 of the second semiconductor package 200. Air flows smoothly along the clearance, resulting in an improvement in heat radiation efficiency. An adhesive layer (not shown) may be interposed between the two semiconductor packages 100 and 200, i.e. between the first encapsulant 140 of the first semiconductor package 100 and the second substrate 220 of the second semiconductor package 200, to achieve improved mechanical bonding between the two semiconductor packages 100 and 200.

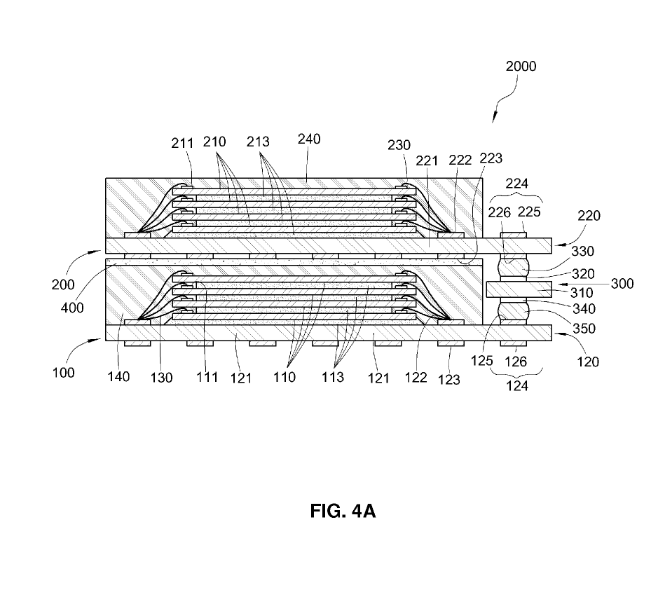

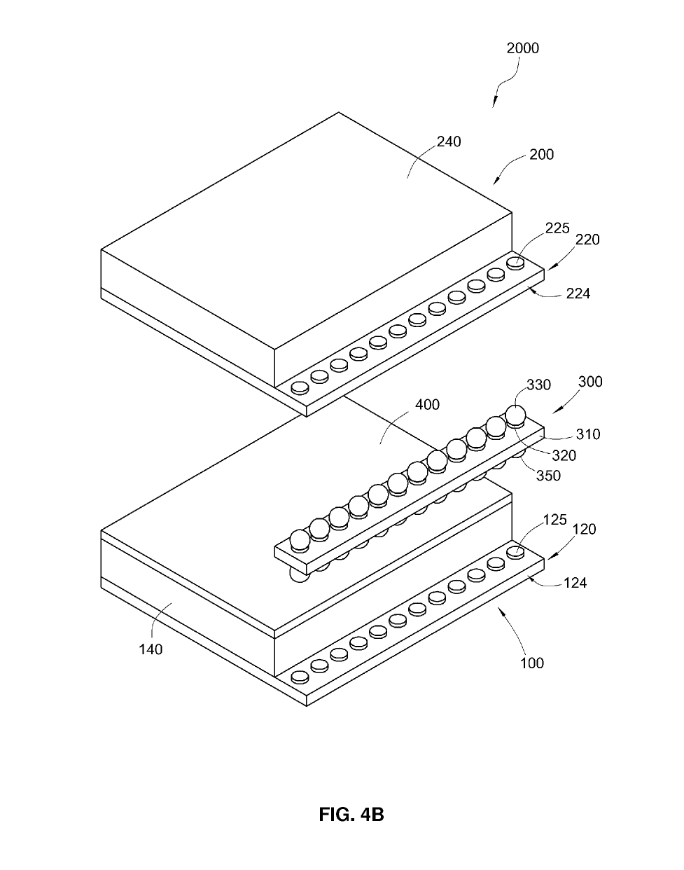

FIGS. 4a and 4b are a longitudinal cross-sectional view and an exploded perspective view showing a stackable semiconductor package according to another embodiment of the present invention, respectively.

As shown in FIGS. 4a and 4b, the stackable semiconductor package 2000 has a structure similar to the semiconductor package 1000 according to the previous embodiment of the present invention. Herein, the same reference numerals are given to the same elements as the elements described in the previous embodiment, and only differences between the embodiments will be explained below.

The semiconductor package 2000 comprises a first semiconductor package 100 and a second semiconductor package 200 wherein the first semiconductor package 100 includes a first substrate 120 formed with only one first extension 124 and the second semiconductor package 200 includes a second substrate 220 formed with only one second extension 224. Specifically, the first extension 124 extends horizontally outside the periphery of a first encapsulant 140 of the first semiconductor package 100 and the second extension 224 extends horizontally outside the periphery of a second encapsulant 240 of the second semiconductor package 200. As a result, only one interposer 300 is positioned in the shape of a rectangular plate (‘—’) between the first extension 124 and the second extension 224.

Since the interposer 300 is the only member to mechanically connect the first semiconductor package 100 to the second semiconductor package 200, the mechanical bonding between the two semiconductor packages 100 and 200 may be reduced. An adhesive layer 400 is interposed between the two semiconductor packages 100 and 200, i.e. between the first encapsulant 140 of the first semiconductor package 100 and the second substrate 220 of the second semiconductor package 200, to enhance the mechanical bonding between the two semiconductor packages 100 and 200.

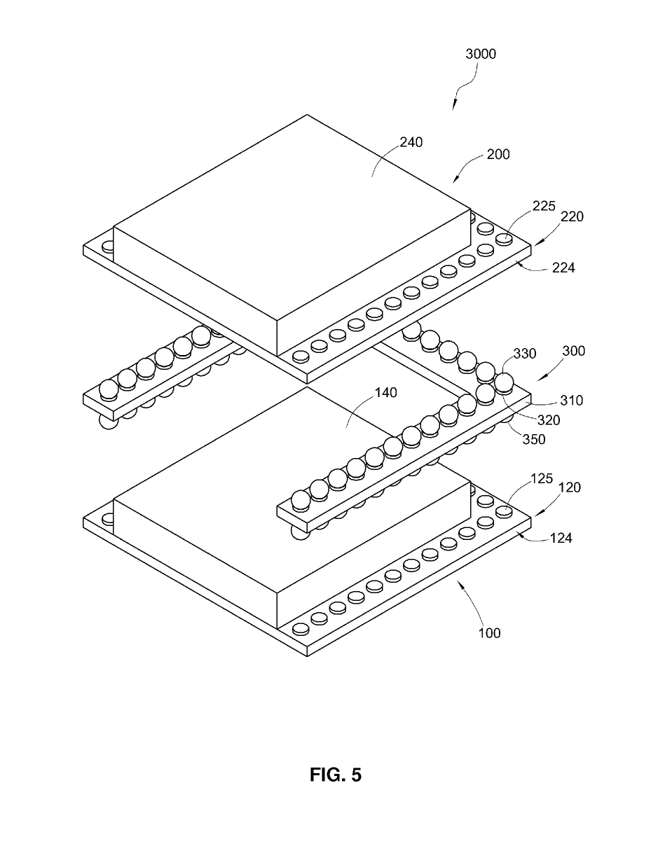

FIG. 5 is an exploded perspective view showing a stackable semiconductor package according to another embodiment of the present invention.

As shown in FIG. 5, the stackable semiconductor package 3000 has a structure similar to the semiconductor package 1000 according to the previous embodiment of the present invention. Herein, the same reference numerals are given to the same elements as the elements described in the previous embodiment, and only differences between the embodiments will be explained below.

The semiconductor package 3000 comprises a first semiconductor package 100 and a second semiconductor package 200 wherein the first semiconductor package 100 includes a first substrate 120 formed with three first extensions 124 and the second semiconductor package 200 includes a second substrate 220 formed with three second extensions 224. Specifically, the first extensions 124 extend horizontally outside the periphery of a first encapsulant 140 of the first semiconductor package 100 and the second extensions 224 extend horizontally outside the periphery of a second encapsulant 240 of the second semiconductor package 200. As a result, an interposer 300 is positioned in a [symbol] shape between the first extensions 124 and the second extensions 224. Although the interposer 300 is formed in one piece in FIG. 5, it may be separated into three independent forms. There is no restriction on the shape of the interposer 300.

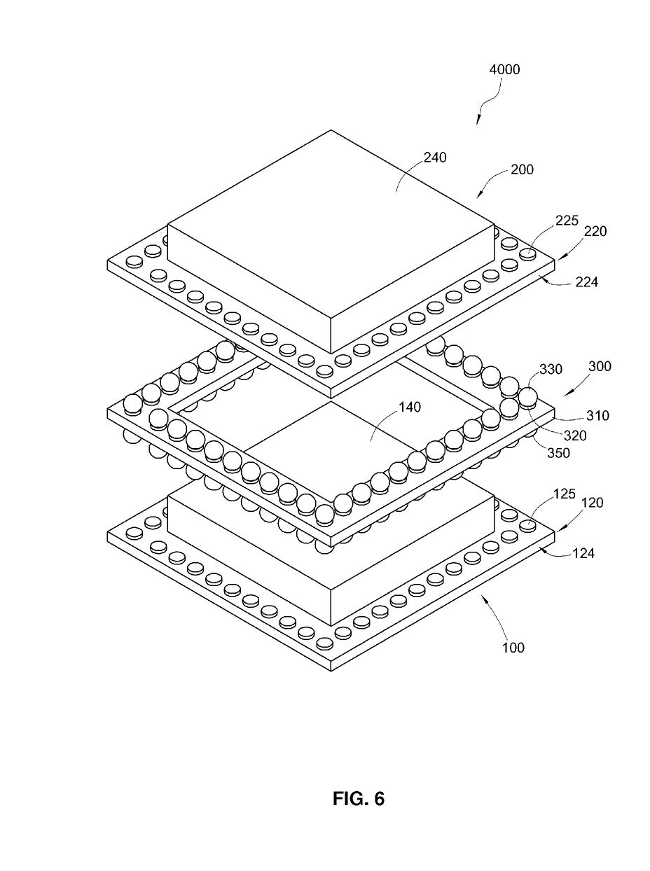

FIG. 6 is an exploded perspective view showing a stackable semiconductor package according to another embodiment of the present invention.

As shown in FIG. 6, the stackable semiconductor package 4000 has a structure similar to the semiconductor package 1000 according to the previous embodiment of the present invention. Herein, the same reference numerals are given to the same elements as the elements described in the previous embodiment, and only differences between the embodiments will be explained below.

The semiconductor package 4000 comprises a first semiconductor package 100 and a second semiconductor package 200 wherein the first semiconductor package 100 includes a first substrate 120 formed with four first extensions 124 and the second semiconductor package 200 includes a second substrate 220 formed with four second extensions 224. Specifically, the first extensions 124 extend horizontally outside the periphery of a first encapsulant 140 of the first semiconductor package 100 and the second extensions 224 extend horizontally outside the periphery of a second encapsulant 240 of the second semiconductor package 200. As a result, an interposer 300 is positioned in a ‘□’ shape between the first extensions 124 and the second extensions 224. Although the interposer 300 is formed in one piece in FIG. 6, it may be separated into four independent forms. There is no restriction on the shape of the interposer 300.

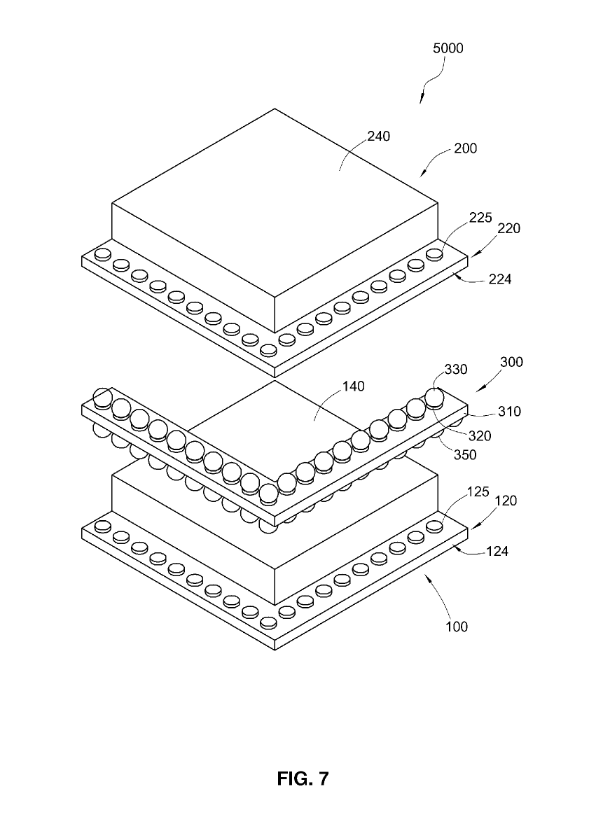

FIG. 7 is an exploded perspective view showing a stackable semiconductor package according to another embodiment of the present invention.

As shown in FIG. 7, the stackable semiconductor package 5000 has a structure similar to the semiconductor package 1000 according to the previous embodiment of the present invention. Herein, the same reference numerals are given to the same elements as the elements described in the previous embodiment, and only differences between the embodiments will be explained below.

The semiconductor package 5000 comprises a first semiconductor package 100 and a second semiconductor package 200 wherein the first semiconductor package 100 includes a first substrate 120 formed with two first extensions 124 and the second semiconductor package 200 includes a second substrate 220 formed with two second extensions 224. Specifically, the first extensions 124 extend horizontally outside the periphery of a first encapsulant 140 of the first semiconductor package 100 and the second extensions 224 extend horizontally outside the periphery of a second encapsulant 240 of the second semiconductor package 200. As a result, an interposer 300 is positioned in a [symbol] shape between the first extensions 124 and the second extensions 224. Although the interposer 300 is formed in one piece in FIG. 7, it may be separated into two independent forms. There is no restriction on the shape of the interposer 300.

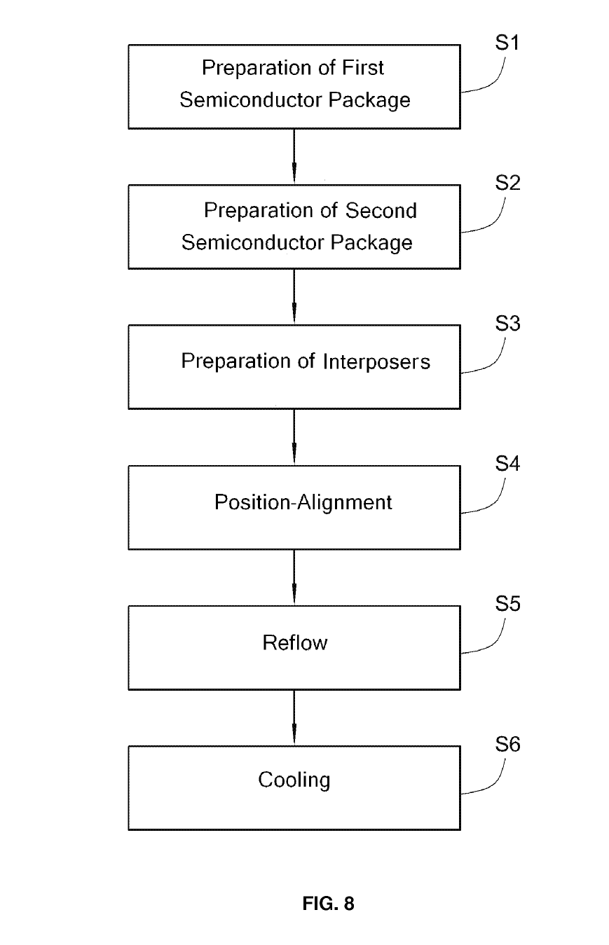

FIG. 8 is a flow chart illustrating a stack method of a stackable semiconductor package according to the present invention. The stackable semiconductor package 1000 shown in FIGS. 3a and 3b will be herein illustrated, but the other stackable semiconductor packages 2000, 3000, 4000 and 5000 is almost identical to the stackable semiconductor package 1000, and description thereof is omitted.

As shown in FIG. 8, the stack method of the present invention comprises the following steps: preparation of a first semiconductor package (S1), preparation of a second semiconductor package (S2), preparation of an interposer (S3), position-alignment (S4), reflow (S5) and cooling (S6). A more detailed explanation of the stack method according to the present invention will be given below.

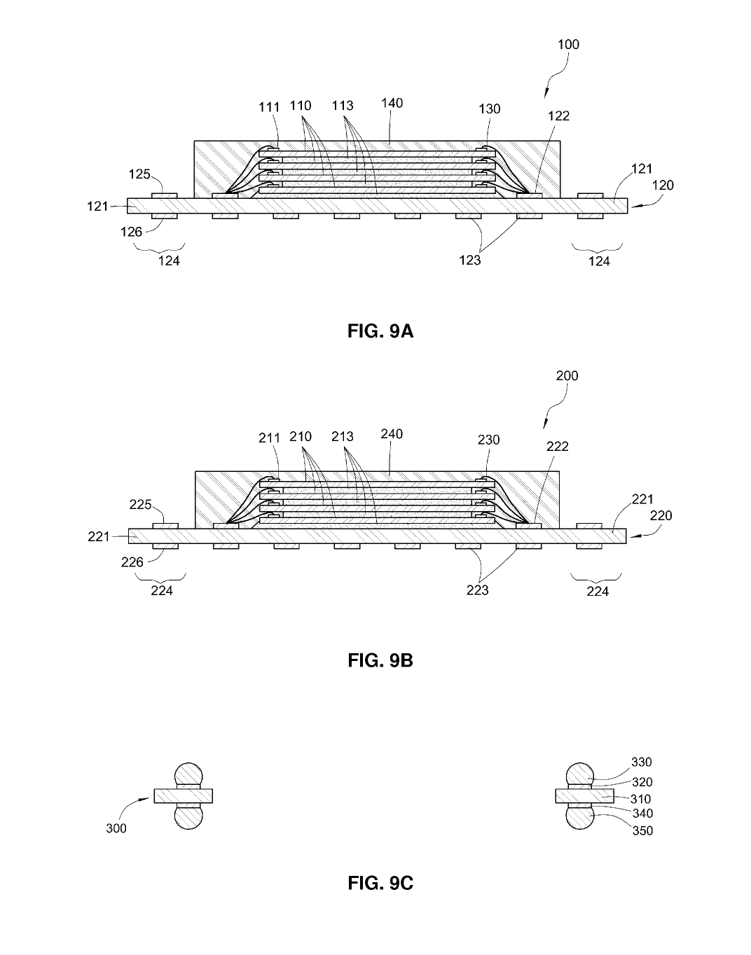

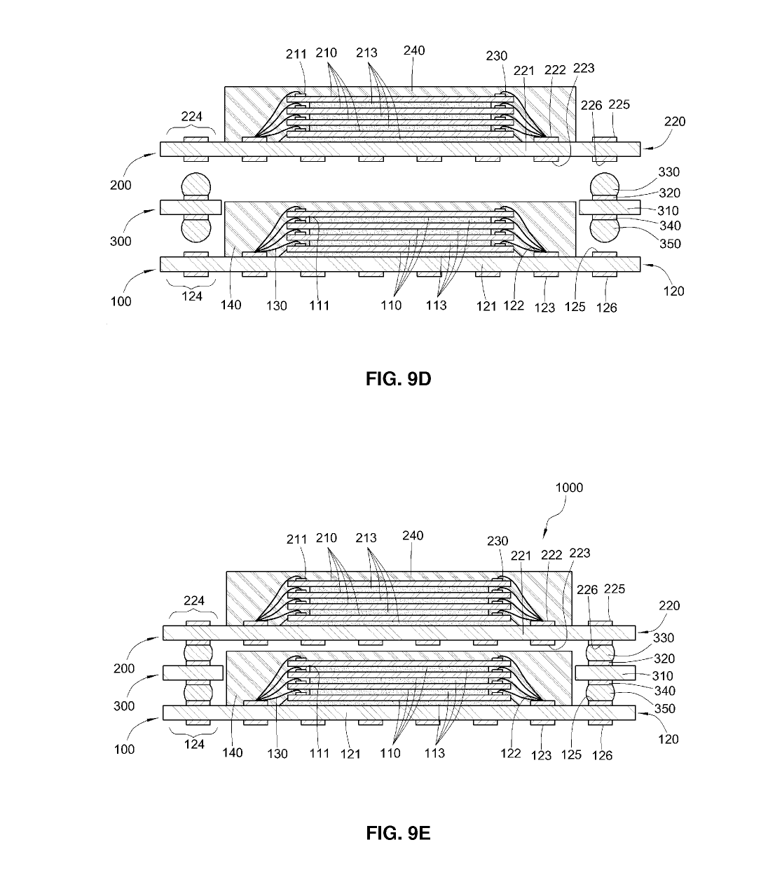

FIGS. 9a through 9d are cross-sectional views sequentially illustrating the stack method of the present invention.

As shown in FIG. 9a, first semiconductor dies 110 are adhered and electrically connected to a first substrate 120 by means of an adhesive and first conductive wires 130, respectively. The first semiconductor dies 110 and the first conductive wires 130 are encapsulated with a first encapsulant 140 to complete the preparation of a first semiconductor package 100. It is to be understood that, instead of the first conductive wires 130, conductive bumps can be used to electrically connect the first semiconductor dies 110 to the first substrate 120. First extensions 124 of a prescribed length are formed outside the periphery of the first encapsulant 140 of the first substrate 120. The first extensions 124 are provided with first upper conductive pads 125 and first lower conductive pads 126, which are electrically connected to one another through respective conductive vias.

As shown in FIG. 9b, second semiconductor dies 210 are adhered and electrically connected to a second substrate 220 by means of an adhesive and second conductive wires 230, respectively. The second semiconductor dies 210 and the second conductive wires 230 are encapsulated with a second encapsulant 240 to prepare a second semiconductor package 200. It is to be understood that, instead of the second conductive wires 230, conductive bumps can be used to electrically connect the second semiconductor dies 210 to the second substrate 220. Second extensions 224 of a prescribed length are formed outside the periphery of the second encapsulant 240 of the second substrate 220. The second extensions 224 are provided with second upper conductive pads 225 and second lower conductive pads 226, which are electrically connected to one another through respective conductive vias.

As shown in FIG. 9c, one or more interposers 300 are prepared by sequentially forming upper conductive pads 320 and upper solder balls 330 on the upper surface of an insulating layer 310, and sequentially forming lower conductive pads 340 and lower solder balls 350 on the lower surface of the insulating layer 310.

One to four interposers may be formed between the first substrate 120 and the second substrate 220. There is no restriction on the number of the interposers. The shape of the interposers between the first substrate 120 and the second substrate 220 may be selected from, but is not limited to, ‘—’, [symbol] and ‘□’ shapes.

As shown in FIG. 9d, the interposers 300 are positioned and aligned between the first substrate 120 and the second substrate 220 such that the upper solder balls 330 come into contact with the second substrate 220 and the lower solder balls 350 come into contact with the second substrate 120. More specifically, the upper solder balls 330 of the interposers 300 are temporarily brought into contact with the second lower conductive pads 226 provided under the second extensions 224 of the second substrate 220, and the lower solder balls 350 of the interposers 300 are temporarily brought into contact with the first upper conductive pads 125 provided on the first extensions 124 of the first substrate 120. A highly viscous material, such as a flux or a solder paste, may be interposed between the solder balls and the conductive pads to allow the temporary contact to be more stably maintained.

As shown in FIG. 9e, the first semiconductor package 100, the second semiconductor package 200 and the interposers 300 are placed in a furnace at a temperature of 180 to 300° C. to melt the upper and lower solder balls so that the upper solder balls 330 are electrically connected to the second substrate 220 and the lower solder balls 350 are electrically connected to the first substrate 120. Namely, the upper solder balls 330 are melted to be electrically and mechanically connected to the second lower conductive pads 226 provided under the second extensions 224 of the second substrate 220, and the lower solder balls 350 are melted to be electrically and mechanically connected to the first upper conductive pads 125 provided on the first extensions 124 of the first substrate 120. In the case where a flux is used for the temporary contact in the previous step, it is completely volatilized and removed at the high temperature.

Thereafter, the first semiconductor package 100, the second semiconductor package 200 and the interposers 300 are slowly allowed to cool to room temperature to cure the upper solder balls 330 and the lower solder balls 350. This curing hardens the upper solder balls 330 and the lower solder balls 350 to ensure a stable mechanical and electrical connection between the first substrate 120 and the second substrate 220.

As apparent from the foregoing, the stackable semiconductor package of the present invention comprises extensions extending horizontally outside the periphery of encapsulants of LGA or BGA semiconductor packages. The extensions serve as basic structures on which a plurality of semiconductor packages can be stacked. In addition, one or more interposers having electrical conduction paths are used to electrically connect upper and lower semiconductor packages stacked in the vertical direction to each other, thus simultaneously achieving stacking and electrical connection of the semiconductor packages. That is, the use of the extensions and the interposers enables stacking of LGA or BGA semiconductor packages in an easy manner, which could not be achieved by the prior art.

Although the stackable semiconductor package and the stack method of the stackable semiconductor package according to the present invention have been described with reference to the foregoing embodiments, these embodiments are set forth for illustrative purposes and do not serve to limit the invention. Those skilled in the art will readily recognize and appreciate that various variations and modifications can be made without departing from the spirit and scope of the present invention as defined in the appended claims. Accordingly, such variations and modifications are encompassed within the spirit and scope of the present invention.

What is claimed is:

1. A stackable semiconductor package comprising a substrate, at least one semiconductor die mounted on the substrate to be electrically connected to the substrate, and an encapsulant molded on the substrate to surround the semiconductor die wherein the substrate is formed with at least one extension extending outside the outer circumference of the encapsulant, and the extension is provided with upper and lower conductive pads electrically connected to one another and exposed to the outside for package stacking on its upper and lower surfaces.

2. A stackable semiconductor package comprising:
a first semiconductor package including a first substrate, at least one first semiconductor die mounted on the first substrate to be electrically connected to the first substrate, and a first encapsulant molded on the first substrate to surround the first semiconductor die;
a second semiconductor package including a second substrate, at least one second semiconductor die mounted on the second substrate to be electrically connected to the second substrate, and a second encapsulant molded on the second substrate to surround the second semiconductor die; and
one or more interposers positioned between the first and second semiconductor packages to electrically connect the first substrate to the second substrate so that the first and second semiconductor packages are stacked in the vertical direction.

3. The stackable semiconductor package according to claim 2, wherein each of the interposers includes an insulating layer, lower conductive pads formed on the lower surface of the insulating layer to be electrically connected to the first substrate of the first semiconductor package, and upper conductive pads formed on the upper surface of the insulating layer opposite to the lower conductive pads to be electrically connected to the second substrate of the second semiconductor package, the upper and lower conductive pads being electrically connected to one another.

4. The stackable semiconductor package according to claim 2, wherein the interposers are electrically connected to the first substrate and the second substrate by lower solder balls and upper solder balls, respectively.

5. The stackable semiconductor package according to claim 2, wherein one to four interposers are formed between the first and second substrates.

6. The stackable semiconductor package according to claim 2, wherein the shape of the interposers between the first and second substrates is selected from ‘—’, [symbol] and ‘□’ shapes.

7. The stackable semiconductor package according to claim 2, wherein the first substrate is formed with at least one first extension extending outside the outer circumference of the first encapsulant, and the first extension is provided with first upper and lower conductive pads electrically connected to the interposers and one another on its upper and lower surfaces.

8. The stackable semiconductor package according to claim 2, wherein the second substrate is formed with at least one second extension extending outside the outer circumference of the second encapsulant, and the second extension is provided with second upper and lower conductive pads electrically connected to the interposers and one another on its upper and lower surfaces.

9. A stack method of a stackable semiconductor package, the method comprising the steps of:
mounting at least one first semiconductor die on a first substrate to electrically connect the first substrate to the first semiconductor die, and encapsulating the first semiconductor die with a first encapsulant to prepare a first semiconductor package;
mounting at least one second semiconductor die on a second substrate to electrically connect the second substrate to the second semiconductor die, and encapsulating the second semiconductor die with a second encapsulant to prepare a second semiconductor package;
preparing one or more interposers, each of which includes an insulating layer, lower conductive pads and lower solder balls sequentially formed on the lower surface of the insulating layer, and upper conductive pads and upper solder balls sequentially formed on the upper surface of the insulating layer;
positioning and aligning the interposers between the first and second substrates such that the lower solder balls come into contact with the first substrate and the upper solder balls come into contact with the second substrate;
placing the first semiconductor package, the second semiconductor package and the interposers in a furnace at a temperature of 180 to 300° C. to melt the upper and lower solder balls so that the lower solder balls are electrically connected to the first substrate and the upper solder balls are electrically connected to the second substrate (reflow); and
cooling the first semiconductor package, the second semiconductor package and the interposers to room temperature to cure the upper and lower solder balls.

10. The method according to claim 9, wherein, in the step of preparing the interposers, each of the interposers includes an insulating layer, lower conductive pads formed on the lower surface of the insulating layer to be electrically connected to the first substrate of the first semiconductor package, and upper conductive pads formed on the upper surface of the insulating layer opposite to the lower conductive pads to be electrically connected to the second substrate of the second semiconductor package, the upper and lower conductive pads being electrically connected to one another.

11. The method according to claim 10, wherein, in the step of preparing the interposers, lower solder balls are attached to the lower conductive pads and upper solder balls are attached to the upper conductive pads.

12. The method according to claim 9, wherein, in the step of preparing the interposers, one to four interposers are formed between the first and second substrates.

13. The method according to claim 9, wherein, in the step of preparing the interposers, the shape of the interposers between the first and second substrates is selected from ‘—’, [symbol] and ‘□’ shapes.

14. The method according to claim 9, wherein, in the step of preparing the first semiconductor package, the first substrate is formed with at least one first extension extending outside the outer circumference of the first encapsulant, and the first extension is provided with first upper and lower conductive pads electrically connected to the interposers and one another on its upper and lower surfaces.

15. The method according to claim 9, wherein, in the step of preparing the second semiconductor package, the second substrate is formed with at least one second extension extending outside the outer circumference of the second encapsulant, and the second extension is provided with second upper and lower conductive pads electrically connected to the interposers and one another on its upper and lower surfaces.
